(19) United States
(12) Patent Application Publication
(10) Pub. No.: US 2014/0230879 A1
(43) Pub. Date: Aug. 21, 2014

(54) PHOTOVOLTAIC MODULE

(71) Applicant: AU Optronics Corporation, Hsin-Chu (TW)

(72) Inventor: Yen-Cheng HU, HSIN-CHU (TW)

(73) Assignee: AU Optronics Corporation, Hsin-Chu (TW)

(21) Appl. No.: 14/182,458

(22) Filed: Feb. 18, 2014

(30) Foreign Application Priority Data
Feb. 18, 2013 (CN) 201310052722.7

(51) Int. Cl. H01L 31/05

(52) U.S. Cl. CPC H01L 31/0508
USPC 136/244

(57) ABSTRACT

A photovoltaic module includes at least two photovoltaic cells and a ribbon. Each of the photovoltaic cells includes a photovoltaic device, a surface electrode, and a back electrode. The photovoltaic device has a light-receiving surface and a back surface opposite the light-receiving surface. The surface electrode is disposed on the light-receiving surface of the photovoltaic device. The surface electrode includes at least one bus electrode and a plurality of finger electrodes. The bus electrode includes at least two line electrodes disposed on the light-receiving surface of the photovoltaic device. The finger electrodes are disposed on the light-receiving surface of the photovoltaic device and extend in a direction different from the lengthwise direction of the bus electrode. The back electrode is disposed on the back surface of the photovoltaic device. The ribbon electrically connects to the photovoltaic cells.

### RELATED APPLICATIONS

This application claims priority to China Application Serial Number 201310052722.7, filed Feb. 18, 2013, which is herein incorporated by reference.

### BACKGROUND

1. Technical Field

The present disclosure relates to photovoltaic modules.

2. Description of Related Art

Due to a gradual depletion of the traditional fossil fuel, renewable sources of energy are being developed to fulfill global needs of energy consumption. Among all the renewable sources of energy, solar energy is a type having a great potential.

Solar cells convert solar energy to electricity by a method called photovoltaic effect. Conventionally, there are several kinds of solar cells, such as crystal silicon solar cells, thin film solar cells, dye-sensitized solar cells (DSSCs), tandem cells, etc, wherein the crystal silicon solar cell is currently one of the most widely used among all.

To build the normal crystal silicon solar cell, the manufacturer often prints silver pastes onto a light-receiving surface of a photovoltaic device as a surface electrode. However, due to its band formation leading to a tremendous material cost of the silver paste, it is very expensive for producing a bus electrode. Therefore, the production cost of the crystal silicon solar cell remains high, avoiding further applications and promotions of the technology.

### SUMMARY

One aspect of the present invention is to provide a photovoltaic module as a solution for fixing a difficulty mentioned in related art.

An embodiment of the present invention provides a photovoltaic module comprising at least two photovoltaic cells and a ribbon. Each of the photovoltaic cells includes a photovoltaic device, a surface electrode, and a back electrode. The photovoltaic device has a light-receiving surface and a back surface opposite the light-receiving surface. The surface electrode is disposed on the light-receiving surface of the photovoltaic device. The surface electrode includes at least one bus electrode and a plurality of finger electrodes. The bus electrode includes at least two line electrodes disposed on the light-receiving surface of the photovoltaic device. The finger electrodes are disposed on the light-receiving surface of the photovoltaic device and extend in a direction different from the lengthwise direction of the bus electrode. The finger electrodes intersect and are electrically connected with the line electrodes, each of the finger electrodes is disposed partially out of a region where the bus electrodes is disposed, and any adjacent two of the line electrodes and any adjacent two of the finger electrodes define an electrodeless space in the region where the bus electrodes is disposed. The back electrode is disposed on the back surface of the photovoltaic device. The ribbon electrically connects the photovoltaic cells, and the ribbon is partially disposed on the light-receiving surface of the photovoltaic device of one of the photovoltaic cells and covers the line electrodes of the bus electrodes.

In one or multiple embodiments of the present invention, the electrodeless space occupies about 52% to 72% of a volume of the bus electrodes.

In one or multiple embodiments of the present invention, the region where the bus electrodes is disposed comprises a central region and a pair of edge regions disposed on opposite sides of the central region, and the line electrodes disposed in the central region are denser than those disposed in the edge regions.

In one or multiple embodiments of the present invention, the central region occupies at least about a half of the volume of the bus electrodes.

In one or multiple embodiments of the present invention, the region where the bus electrode is disposed comprises a central region and a pair of edge regions disposed on opposite sides of the central region, and a line width of each line electrode disposed in the central region are wider than those disposed in the edge regions.

In one or multiple embodiments of the present invention, the line widths of the line electrodes are substantially the same.

In one or multiple embodiments of the present invention, a line width of each line electrodes is wider than a line width of each finger electrode.

In one or multiple embodiments of the present invention, a line width of each line electrode is about 40 μm to 1 mm.

In one or multiple embodiments of the present invention, the line electrodes are substantially equally spaced.

In one or multiple embodiments of the present invention, the intervals of the line electrodes get smaller as the intervals of the line electrodes get nearer to the central region where the bus electrodes is disposed.

In one or multiple embodiments of the present invention, the surface electrode further comprises at least one band electrode. The band electrode is disposed on the light-receiving surface of the photovoltaic device, intersects with and is electrically connected with the finger electrodes. A line width of the band electrode is substantially the same as a line width of the bus electrode.

In one or multiple embodiments of the present invention, a plurality of the bus electrodes are arranged separately on the light-receiving surface of the photovoltaic device.

In one or multiple embodiments of the present invention, the bus electrode further comprises at least a pair of end-part electrodes for constituting a shape of frame together with opposite two of the line electrodes.

In one or multiple embodiments of the present invention, each line width of the line electrode is about 40 μm to 100 μm.

Yet in another embodiment of the present invention, a photovoltaic module comprises at least two photovoltaic cells and at least one ribbon. Each of the photovoltaic cell comprises photovoltaic device, surface electrode, and back electrode. The photovoltaic device has a light-receiving surface and a back surface in opposed sides. The surface electrode is disposed on the light-receiving surface of the photovoltaic device, which further comprises at least a bus electrodes and a plurality of finger electrodes. The bus electrode comprises at least two line electrodes, disposed on the light-receiving surface, and the finger electrodes, disposed on the light-receiving surface and electrically connected with outermost line electrodes. Any adjacent two of the line electrodes define an electrodeless space. The finger electrodes disposed on the light-receiving surface electrically connects to only the outermost line electrodes. The back electrode is disposed on the back surface of the photovoltaic device. The ribbon electrically connects the photovoltaic cells, which is partially disposed on the light-receiving surface of the photovoltaic device in the photovoltaic cells and covers the line electrodes of the bus electrodes.

In one or multiple embodiments of the present invention, the electrodeless space occupies about 52% to 72% of a volume of the bus electrodes.

In one or multiple embodiments of the present invention, the line widths of the line electrodes are substantially the same.

In one or multiple embodiments of the present invention, the line electrodes are substantially equally spaced.

In one or multiple embodiments of the present invention, a line width of each line electrode is about 40 μm to 1 mm.

In one or multiple embodiments of the present invention, a line width of each line electrode is about 40 μm to 100 μm.

### BRIEF DESCRIPTION OF THE DRAWINGS

FIG. 1 is a top view of a photovoltaic cell according to the first embodiment of the present invention;

FIG. 2 is a cross-sectional view taken along a line 2-2 of FIG. 1;

FIG. 3 is a top view of a photovoltaic module including a series of the photovoltaic cells of FIG. 1 electrically connected by ribbons;

FIG. 4 is a cross-sectional view taken along a line 4-4 of FIG. 3;

FIG. 5 shows efficiency curves of the photovoltaic cells according to several embodiments of the present invention;

FIG. 6 is a top view of a photovoltaic cell according to the second embodiment of the present invention;

FIG. 7 is a top view of a photovoltaic cell according to the third embodiment of the present invention;

FIG. 8 is a top view of a photovoltaic cell according to the fourth embodiment of the present invention;

FIG. 9 is a top view of a photovoltaic cell according to the fifth embodiment of the present invention;

FIG. 10 is a top view of a photovoltaic cell according to the sixth embodiment of the present invention;

FIG. 11 is a top view of a photovoltaic cell according to the seventh embodiment of the present invention;

FIG. 12 is a top view of a photovoltaic cell according to the eighth embodiment of the present invention;

FIG. 13 is a top view of a photovoltaic cell according to the ninth embodiment of the present invention;

FIG. 14 is a top view of a photovoltaic cell according to the tenth embodiment of the present invention;

FIG. 15 is a top view of a photovoltaic cell according to the eleventh embodiment of the present invention; and

FIG. 16 is a graph showing cumulative numbers of photovoltaic cells versus their efficiency according to several working examples of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically depicted in order to simplify the drawings.

### First Embodiment

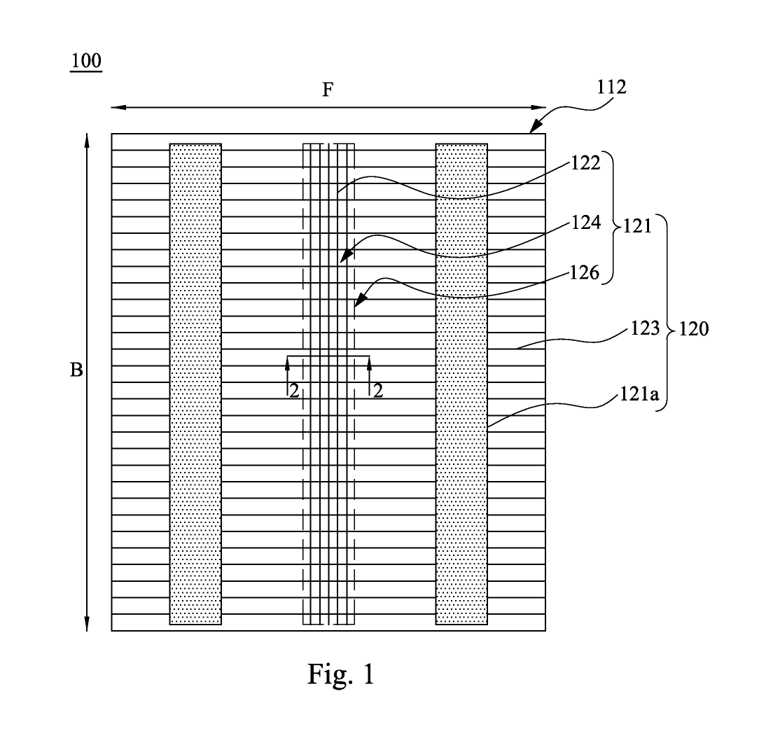

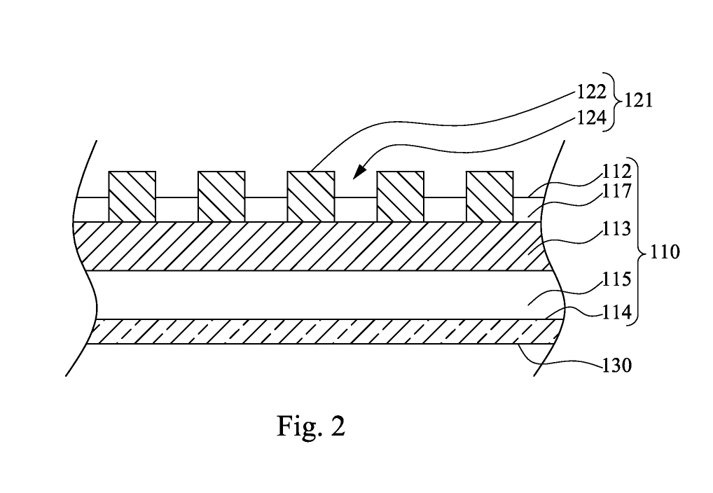

FIG. 1 is a top view of a photovoltaic cell 100 according to the first embodiment of the present invention, and FIG. 2 is a cross-sectional view taken along a line 2-2 of FIG. 1. As shown in FIG. 1 and FIG. 2, a photovoltaic cell 100 includes a photovoltaic device 110, a surface electrode 120, and a back electrode 130. The photovoltaic device 110 has a light-receiving surface 112 and a back surface 114 opposite the light-receiving surface 112. The surface electrode 120 is disposed on the light-receiving surface 112 of the photovoltaic device 110. The surface electrode 120 includes at least one bus electrode 121 and a plurality of finger electrodes 123. The bus electrode 121 includes a plurality of line electrodes 122 disposed on the light-receiving surface 112. The finger electrodes 123 are disposed on the light-receiving surface 112 and extend in a direction different from a lengthwise direction of the bus electrode 121. The finger electrodes 123 intersect and electrically connected with the line electrodes 122. Each of the finger electrodes 123 is disposed partially out of a region 126 where the bus electrode 121 is disposed. Any adjacent two of the line electrodes 122 and any adjacent two of the finger electrodes 123 define an electrodeless space 124 in the region 126 where the bus electrodes 121 is disposed. The back electrode 130 is disposed on the back surface 114 of the photovoltaic device 110.

In this embodiment, since the bus electrode 121 includes a plurality of the line electrodes 122, not a single band electrode, the electrodeless spaces 124 exist in the bus electrode 121. More specifically, the electrodeless space 124 means a space excluding any material the same as the surface electrode 120. For example, when the surface electrode 120 is made of silver paste, the electrodeless space 124 can be considered a space without any silver paste. An existence of the electrodeless space 124 allows reducing a usage of the silver paste, thereby reducing the production cost of the photovoltaic cell 100.

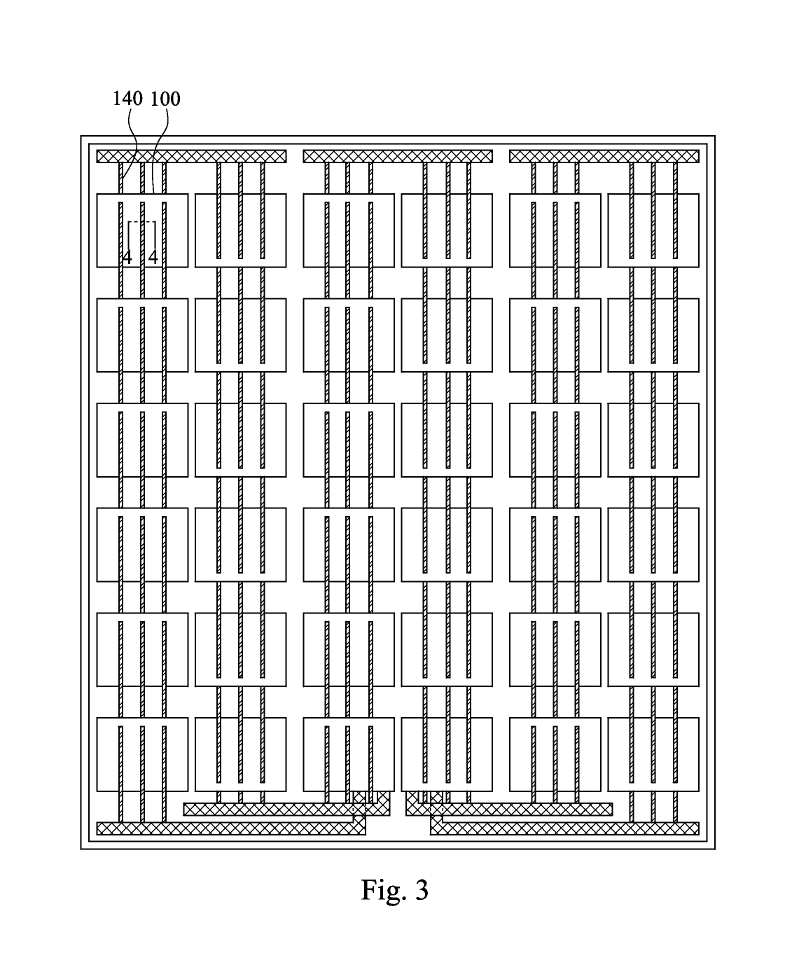

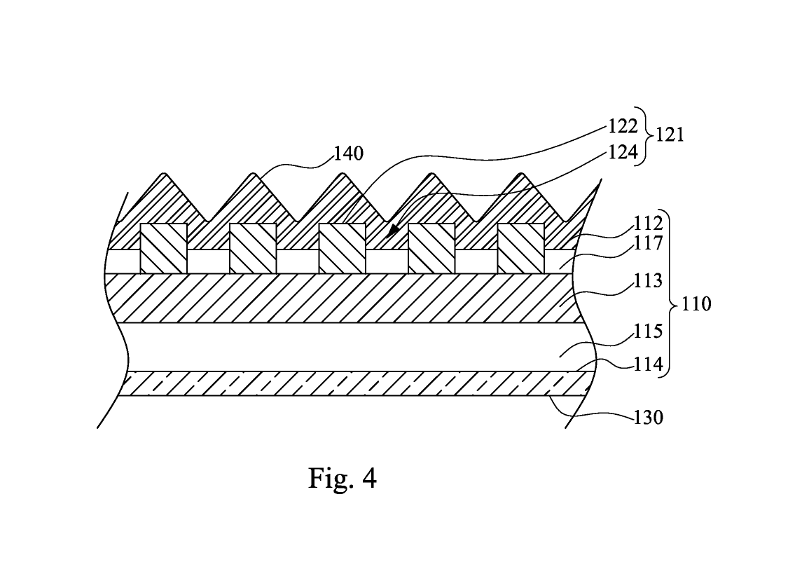

FIG. 3 is a top view of a photovoltaic module including a series of the photovoltaic cells 100 of FIG. 1 electrically connected in series by a plurality of ribbons 140, and FIG. 4 is a cross-sectional view taken along a line 4-4 of FIG. 3. In practice, as shown in FIGS. 3-4, a plurality of the photovoltaic cells 100 may be electrically connected in series by the ribbons 140 to form the photovoltaic module. Reference is made to FIG. 4, the ribbon 140 covers at least two of the line electrodes 122 in the region 126 where the bus electrode 121 is disposed. Because of the high electrical conductivity of the ribbon 140 which, for example, is made of copper covered by tin, an actual electrical connection can be provided by the ribbon 140 without risking increase in resistance of the bus electrode 121 when replacing the band electrode with the line electrodes 122. Therefore, a combined resistance of the bus electrode 121 and the ribbon 140 is held in an acceptable range, instead of increasing vastly.

In this embodiment, the electrodeless spaces 124 occupy about 52% to 72% of a volume of the bus electrode 121. In addition, since the electrodeless space 124 is defined by any adjacent two of the line electrodes 122 and any adjacent two of the finger electrodes 123, the electrodeless space 124 should be the same in height as the line electrodes 122 and the finger electrodes 123. In this condition, the electrodeless spaces 124 occupy about 52% to 72% of an area of the bus electrode 121 when viewed from top.

It should be noted that the definition of the word “about” can be used to represent any subtle change in quantity, but the change does not alter its essence. For example, “the electrodeless spaces 124 occupy about 52% to 72% of a volume of the bus electrodes 121” not only represents its literal meanings, but also allows that a ratio can be slightly more or less than the range, between 52% to 72%, as long as the photovoltaic cell 100 provides acceptable efficiencies. To avoid redundancy, this definition will be referenced thereafter in the specification and the claims.

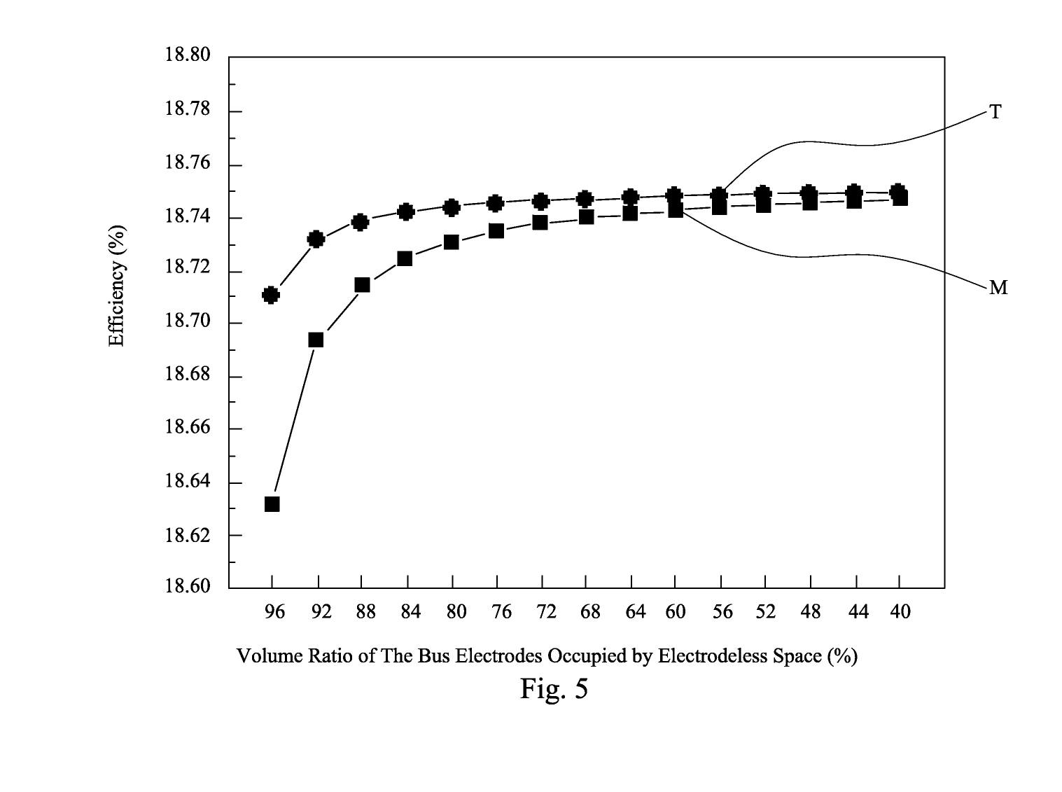

FIG. 5 shows efficiency curves of the photovoltaic cells according to several embodiments of the present invention. In FIG. 5, a width of the region 126 where the bus electrode 121 is disposed is 1.5 mm; a width of each line electrode 122 is 0.06 mm, and the line electrodes 122 are arranged equidistantly and evenly on the region 126 where the bus electrodes 121 is disposed. The efficiency curves are determined under different conditions that the line electrodes 122 have 1, 2, 3, 4, 5, 6, 7, 8, 9, 10, 11, 12, 13, 14 and 15 in quantity, and the volume ratios of the electrodeless spaces 124 in the region 126 are 96%, 92%, 88%, 84%, 80%, 76%, 72%, 68%, 64%, 60%, 56%, 52%, 48%, 44%, and 40%, respectively. A curve T in FIG. 5 represents the efficiency of every entire photovoltaic cell 100, and a curve M in FIG. 5 represents the efficiency of one third of the central part of every photovoltaic cell 100 that contains the bus electrode 121 and its line electrodes 122. It can be told in FIG. 5 that the efficiency of the photovoltaic cell 100 falls in the acceptable range when the volume ratio of the electrodeless spaces 124 in the region 126 is lower than 72%, and the increase of the efficiency of the photovoltaic cell 100 is near to saturation when the volume ratio of the electrodeless spaces 124 in the region 126 is lower than 52%. Thus, the efficiency and the production cost can be balanced according to the results. However, if the volume ratio of the electrodeless spaces 124 in the region 126 is further reduced, it could become hard to manufacture due to unexpected connections or disconnections of the line electrodes 122 in narrow spaces.

Please refer back to FIG. 1. More specifically, the light-receiving surface 112 of the photovoltaic device 110 includes a bus electrode extending direction B and a finger electrode extending direction F, where the bus electrode extending direction B is substantially perpendicular to the finger electrode extending direction F. The bus electrode extending direction B extends across opposite sides of the light-receiving surface 112 of the photovoltaic device 110, and the lengthwise direction of the bus electrode 121 is substantially parallel with the bus electrode extending direction B. The finger electrode extending direction F extends across other opposite sides of the light-receiving surface 112 of the photovoltaic device 110, and the lengthwise direction of each finger electrodes 123 is substantially parallel with the finger electrode extending direction F.

It should be noted that the definition of the word “substantially” can be used to represent any subtle change in quality, but the change does not alter its essence. For example, “the lengthwise direction of the bus electrode 121 is substantially parallel with the bus electrode extending direction B” not only represents its literal meanings, but also allows that the lengthwise direction of the bus electrode 121 can be slightly off-parallel with the bus electrode extending direction B as long as the bus electrodes 121 can deliver negative or positive electrons. To avoid redundancy, this definition will be referenced thereafter in the specification and the claims.

In this embodiment, the line widths of the line electrodes 122 are substantially the same, the line electrodes 122 are substantially equally spaced, and any two of the line electrodes 122 are substantially parallel. Moreover, the line width of each line electrode 122 can be substantially the same as the line width of each finger electrode 123. It should be noted that the embodiments of the line electrodes 122 described above are only examples but not used to limit the claimed scope of the present invention, indicating that the actual embodiment of the line electrodes 122 can be adjusted with respect to different needs in practice for a person having ordinary skill in the art.

Referring back to FIG. 4, when the ribbon 140 covers the line electrodes 122, the ribbon 140 is conformal as a wavy shape along with the line electrodes 122. Therefore, when the light irradiates on the ribbon 140, a part of the light can be scattered or diffused and thus become applicable to the photovoltaic device 110 instead of being reflected entirely.

As shown in FIG. 2 and FIG. 4, the photovoltaic device 110 of this embodiment includes a first-type semiconductor layer 113, a second-type semiconductor layer 115, and an anti-reflective layer 117. The first-type semiconductor layer 113 is stacked over the second-type semiconductor layer 115, and the anti-reflective layer 117 is stacked over the first-type semiconductor layer 113. In this embodiment, the first-type semiconductor layer 113 can be an n-type semiconductor, and the second-type semiconductor layer 115 can be a p-type semiconductor. When the light irradiates on the photovoltaic device 110, the positively charged holes move toward the second-type semiconductor layer 115 (p-type semiconductor), and positive holes flow out through the back electrodes 130; on the contrary, the negatively charged electrons move toward the first-type semiconductor layer 113 (n-type semiconductor), and negative electrons flow out through the surface electrodes (e.g., bus electrodes 121).

The first-type semiconductor layer 113 and the second-type semiconductor layer 115 are made of crystalline silicon, such as monocrystalline silicon or polycrystalline silicon for example. It should be noted that the composition of the first-type semiconductor layer 113 and the second-type semiconductor layer 115 described above are only examples but not used to limit the scope of the present invention, indicating that the composition of the first-type semiconductor layer 113 and the second-type semiconductor layer 115 can be adjusted with respect to different needs in practice for a person having ordinary skill in the art.

Referring back to FIG. 1, the surface electrode 120 further includes a pair of band electrodes 121a. These band electrodes 121a are disposed on the light-receiving surface 112 of the photovoltaic device 110, intersect with and are electrically connected with the finger electrodes 123. A line width of each band electrode 121a is wider than the line width of each line electrode 122. More specifically, each of the band electrode 121a is used as a bus electrode, so the line width of each band electrode 121a and the line width of the bus electrode 121 having the line electrodes 122 are substantially the same, and the band electrodes 121a and the bus electrode 121 having the line electrodes 122 are equidistantly and evenly arranged on the light-receiving surface 112 of the photovoltaic device 100. In FIG. 1, the band electrodes 121a and the bus electrode 121 taken together can be three in quantity, and the bus electrode 121 is disposed between the band electrodes 121a. Specifically, in this embodiment, the line width of each band electrode 121a and/or the bus electrode 121 is about 1 mm to 2 mm, the line width of each line electrode 122 is about 40 μm to 100 μm, and the line width of each finger electrode is about 40 μm to 100 μm, which are not used to limit the scope of the present invention. The line width of each line electrode 122 can be 0.01 mm to 1 mm or 0.01 mm to 0.15 mm in other embodiments.

It should be noted that the quantity and the positions of the bus electrode 121 and the band electrodes 121a described above are only examples but not used to limit the scope of the present invention, indicating that the quantity and the positions of the bus electrode 121 and the band electrodes 121a can be adjusted with respect to different needs in practice for a person having ordinary skill in the art.

For example, although the bus electrode 121 is drawn at the center of the light-receiving surface 112 of the photovoltaic device 100 in FIG. 1, the bus electrode 121 can be disposed at one side of the light-receiving surface 112 instead of being limited at the center. The position of the bus electrode 121 can be adjusted with respect to different needs in practice for a person having ordinary skill in the art.

### Second Embodiment

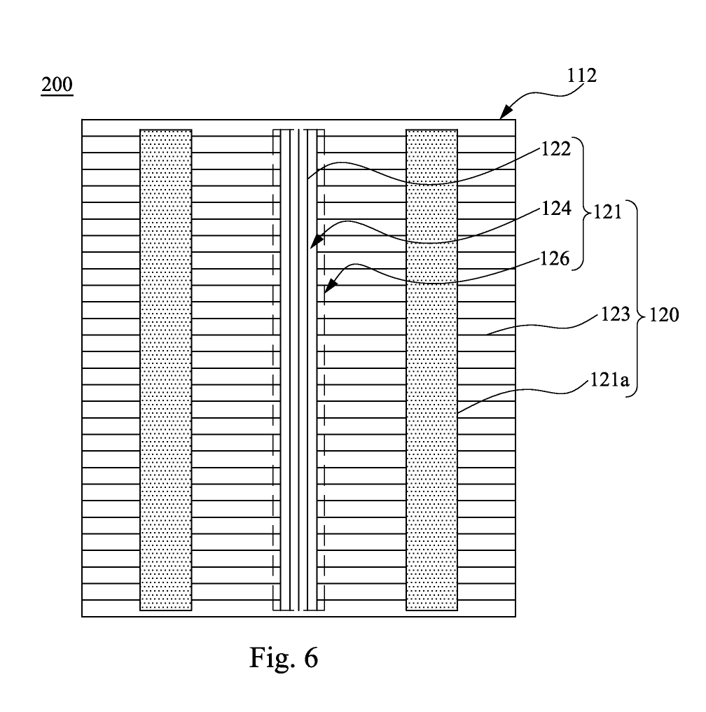

FIG. 6 is a top view of a photovoltaic cell 200 according to the second embodiment of the present invention. The difference between the second embodiment and the first embodiment includes that the finger electrodes 123 of the second embodiment are electrically connected to only the outermost line electrodes 122. Hence, in this embodiment, the electrodeless space 124 is defined by any adjacent two of the line electrodes 122.

To avoid redundancy, other related structural and material details in the second embodiment are referenced to what is described in the first embodiment.

### Third Embodiment

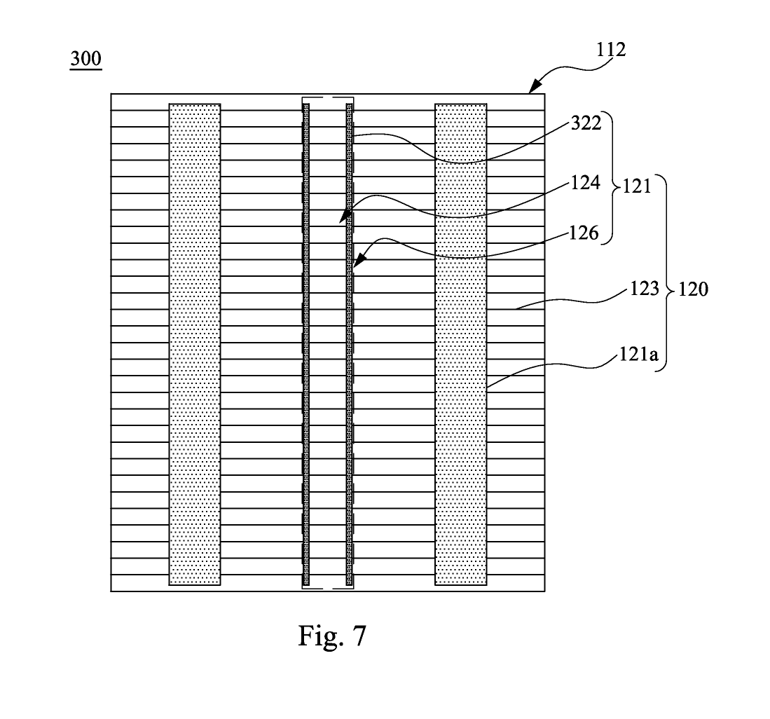

FIG. 7 is a top view of a photovoltaic cell 300 according to the third embodiment of the present invention. The difference between the third embodiment and the first embodiment includes that the line width of each line electrode 322 is wider than the line width of each finger electrodes 123; also, in this embodiment, the line electrodes 322 are two in quantity and separately disposed at opposite sides of the region 126 where the bus electrode 121 is disposed. More specifically, the line width of each line electrode 322 is about 40 μm to 1 mm, and the line width of each finger electrode 123 is about 40 μm to 100 μm in this embodiment.

To avoid redundancy, other related structural and material details in the third embodiment are referenced to what is described in the first embodiment.

### Fourth Embodiment

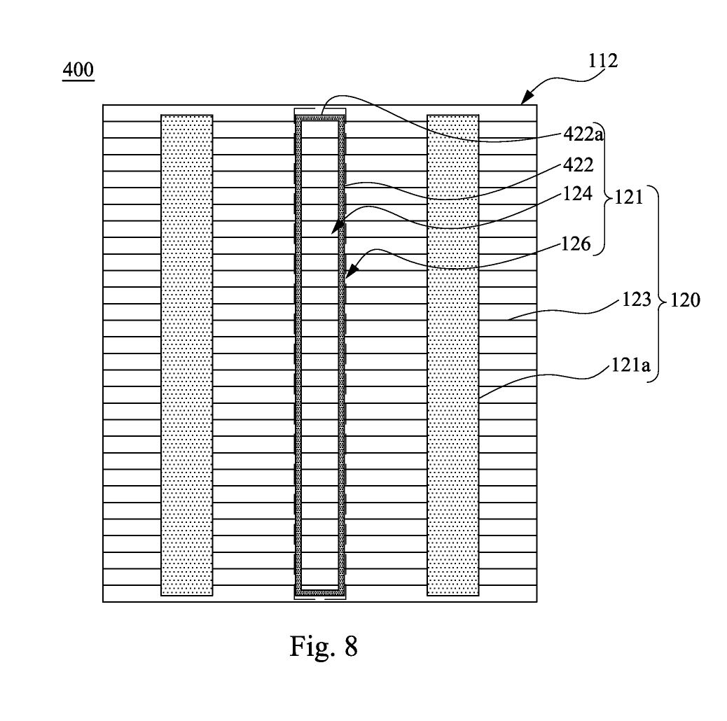

FIG. 8 is a top view of a photovoltaic cell 400 according to the fourth embodiment of the present invention. The difference between the fourth embodiment and the third embodiment includes that the bus electrode 121 further includes at least a pair of end-part electrodes 422a for constituting a shape of frame together with opposite two of the line electrodes 422. In this embodiment, the line width of each end-part electrode 422a is wider than the line width of each finger electrode 123. More specifically, the line width of each end-part electrode 422 is about 40 μm to 1 mm, and the line width of each finger electrode 123 is about 40 μm to 100 μm in this embodiment.

To avoid redundancy, other related structural and material details in the fourth embodiment are referenced to what is described in the third embodiment.

### Fifth Embodiment

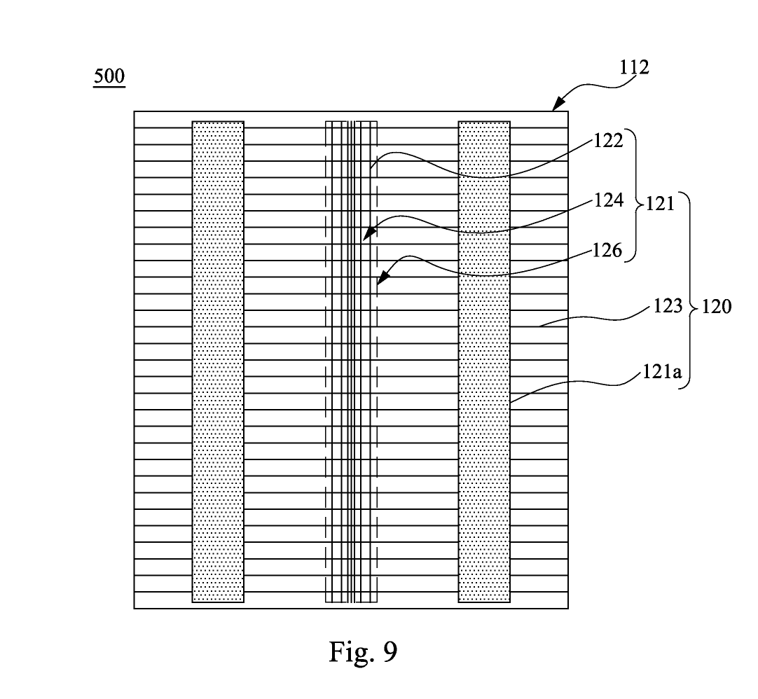

FIG. 9 is a top view of a photovoltaic cell 500 according to the fifth embodiment of the present invention. The difference between the fifth embodiment and the first embodiment includes that intervals of the line electrodes 122 get smaller as the intervals of the line electrodes 122 get nearer to a center of the region 126 where the bus electrode 121 is disposed. A reason to make this design is because when the ribbon 140 is adhered (shown in FIG. 4), a pressure head pressing over the ribbon 140 introduces pressure most likely at the center of the region 126 where the bus electrode 121 is disposed. Hence, if there are denser line electrodes 122 arranged at the center of the region 126 where the bus electrode 121 is disposed, better supports for the pressure head and improvements of process yield can be thus expected.

To avoid redundancy, other related structural and material details in the fifth embodiment are referenced to what is described in the first embodiment.

### Sixth Embodiment

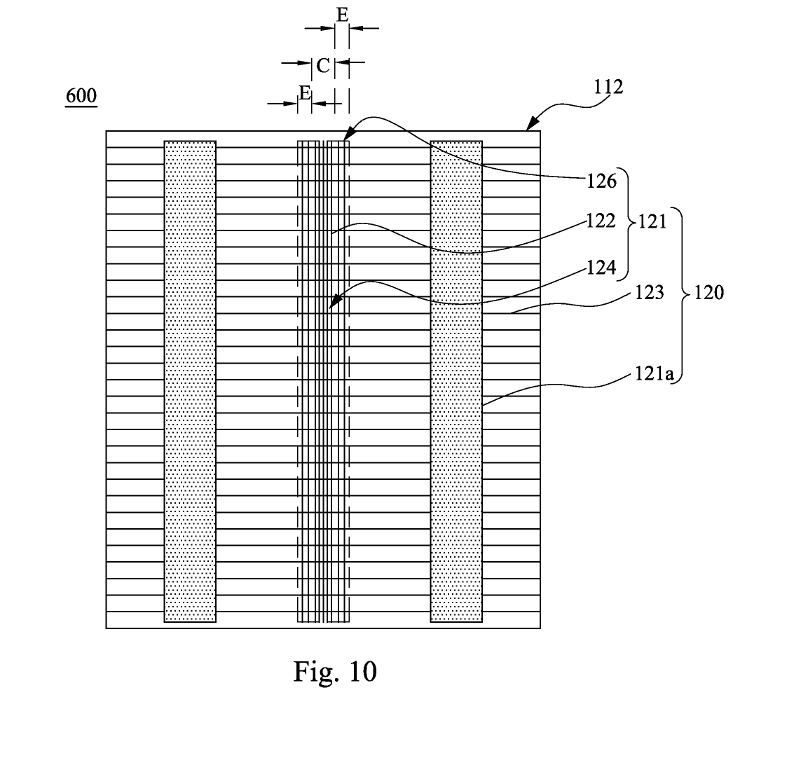

FIG. 10 is a top view of a photovoltaic cell 600 according to the sixth embodiment of the present invention. The difference between the sixth embodiment and the fifth embodiment includes that variations of the intervals of the line electrodes 122 are not continuous but segmentary. As shown in FIG. 10, the region 126 where the bus electrode 121 is disposed can be divided to a central region C and a pair of edge regions E disposed on opposite sides of the central region C. The line electrodes 121 disposed in the central region C are substantially equally spaced, and the line electrodes 121 disposed in the edge regions E are substantially equally spaced as well. However, the interval between any adjacent two of the line electrodes 122 disposed in the central region C is less than that in the edge regions E. That is, the line electrodes 122 disposed in the central region C are denser than those disposed in the edge regions E.

In this embodiment, the central region C occupies at least about a half of the volume of the bus electrode 121 (i.e., the central region C occupies at least about a half of the area of the bus electrode 121 when viewed from top). It should be noted that the volume of the central region C described above is only an example but not used to limit the scope of the present invention, indicating that the volume of the central region C can be adjusted with respect to different needs in practice (e.g., a size of the pressure head) for a person having ordinary skill in the art.

To avoid redundancy, other related structural and material details in the sixth embodiment are referenced to what is described in the fifth embodiment.

### Seventh Embodiment

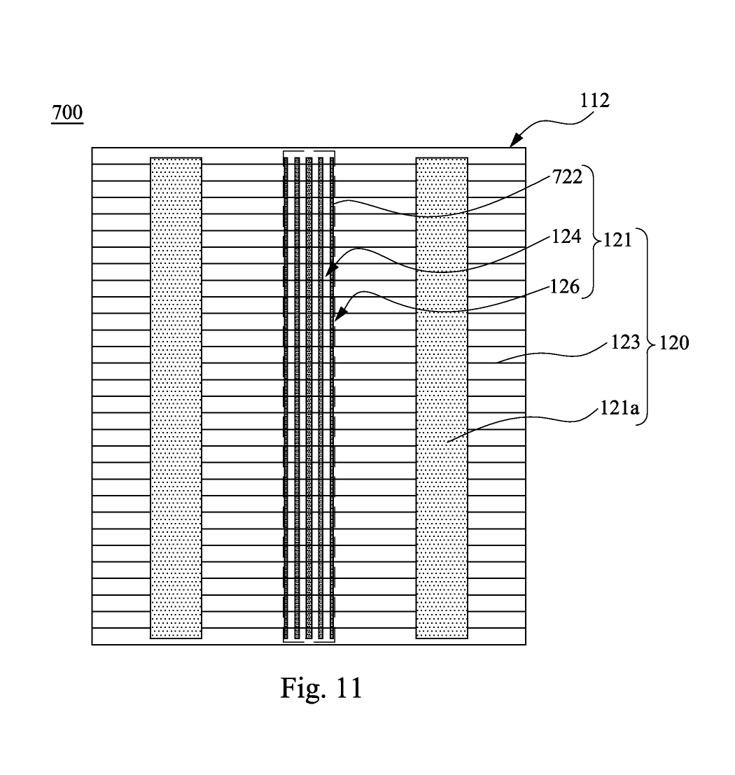

FIG. 11 is a top view of a photovoltaic cell 700 according to the seventh embodiment of the present invention. The difference between the seventh embodiment and the first embodiment includes that the line widths of the line electrodes 722 increase as the line electrodes 722 get nearer to the center of the region 126 where the bus electrode 121 is disposed. A reason to make this design is because when the ribbon 140 is adhered (shown in FIG. 4), a pressure head pressing over the ribbon 140 introduces pressure most likely at the center of the region 126 where the bus electrode 121 is disposed. Hence, if there are wider line electrodes 722 arranged at the center of the region 126 where the bus electrode 121 is disposed, better supports for the pressure head and improvements of process yield can be thus expected.

Additionally, the line width of each line electrode 722 is wider than the line width of each finger electrode 123 in this embodiment. More specifically, the line width of each line electrodes 722 is about 40 μm to 1 mm, and the line width of each finger electrode 123 is about 40 μm to 100 μm.

To avoid redundancy, other related structural and material details in the seventh embodiment are referenced to what is described in the first embodiment.

### Eighth Embodiment

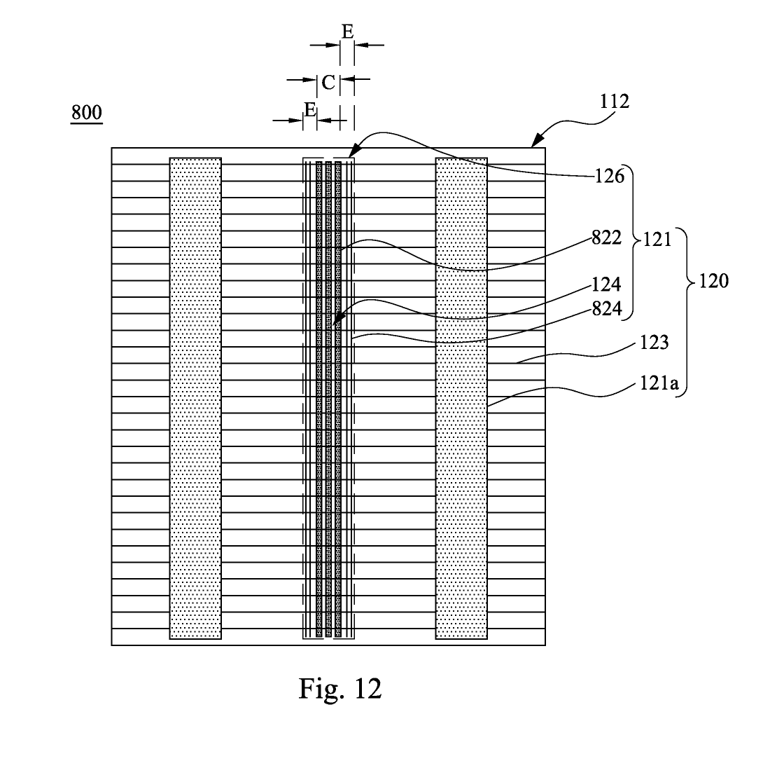

FIG. 12 is a top view of a photovoltaic cell 800 according to the eighth embodiment of the present invention. The difference between the eighth embodiment and the first embodiment includes that variations of the line widths of the line electrodes 822 are not continuous but segmentary. As shown in FIG. 12, the region 126 where the bus electrodes 121 is disposed can be divided to a central region C and a pair of edge regions E disposed on opposite sides of the central region C. The line widths of the line electrodes 822 disposed in the central region C are the same, and the line widths of the line electrodes 824 disposed in the edge regions E are the same as well; however, the line width of each line electrode 822 disposed in the central region C is wider than the line width of each line electrode 824 disposed in the edge regions. More specifically, the line width of each line electrode 822 disposed in the central region C is about 40 μm to 1 mm, and the line width of each line electrode 824 disposed in the edge regions E is about 40 μm to 100 μm.

In this embodiment, the central region C occupies at least a half of the volume of the bus electrodes 121 (i.e., the central region C occupies at least a half of the area of the bus electrodes 121 when viewed from top). It should be noted that the volume of the central region C described above is only an example but not used to limit the scope of the present invention, indicating that the volume of the central region C can be adjusted with respect to different needs in practice (e.g., a size of the pressure head) for a person having ordinary skill in the art.

To avoid redundancy, other related structural and material details in the eighth embodiment are referenced to what is described in the seventh embodiment.

### Ninth Embodiment

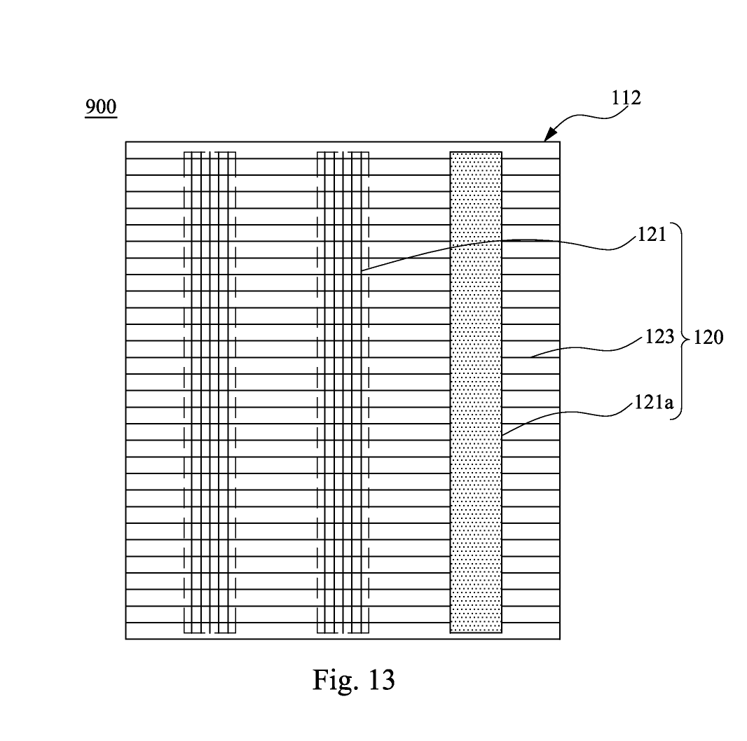

FIG. 13 is a top view of a photovoltaic cell 900 according to the ninth embodiment of the present invention. The difference between the ninth embodiment and the first embodiment includes that the bus electrodes 121 having the line electrodes are two in quantity and are separately arranged on the light-receiving surface 112 of the photovoltaic device. More specifically, one of the bus electrodes 121 is disposed at one side of the light-receiving surface 112 of the photovoltaic device, and the other bus electrode 121 is disposed at the center of the light-receiving surface 112 of the photovoltaic device. In another embodiment, the band electrode 121a can be disposed at the center of the light-receiving surface 112, and the two bus electrodes 121 can be disposed at opposite sides of the band electrode 121a.

It should be noted that the quantity and the position of the bus electrodes 121 described above are only examples but not used to limit the scope of the present invention, indicating that the quantity and the position of the bus electrodes 121 can be adjusted with respect to different needs in practice for a person having ordinary skill in the art.

To avoid redundancy, other related structural and material details in the ninth embodiment are referenced to what is described in the first embodiment.

### Tenth Embodiment

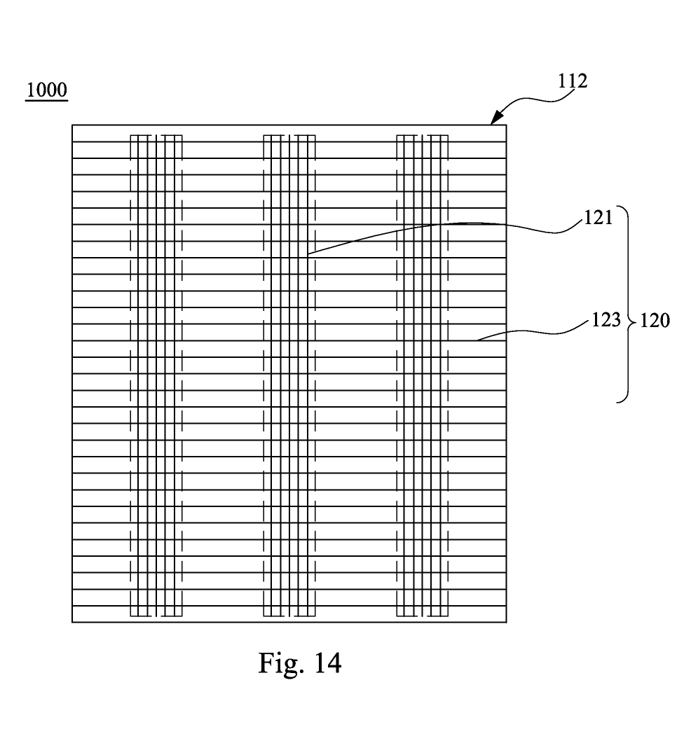

FIG. 14 is a top view of a photovoltaic cell 1000 according to the tenth embodiment of the present invention. The difference between the tenth embodiment and the first embodiment includes that there is no band electrode 121a on the light-receiving surface 112 of the photovoltaic device, and another two bus electrodes 121 having line electrodes are disposed the light-receiving surface 112 of the photovoltaic device instead. The bus electrodes 121 are arranged separately on the light-receiving surface 112 of the photovoltaic device. In FIG. 14, the bus electrodes 121 are three in quantity.

It should be noted that the quantity of the bus electrodes 121 described above is only an example but not used to limit the scope of the present invention, indicating that the quantity of the bus electrodes 121 can be adjusted with respect to different needs in practice for a person having ordinary skill in the art.

To avoid redundancy, other related structural and material details in the tenth embodiment are referenced to what is described in the first embodiment.

### Eleventh Embodiment

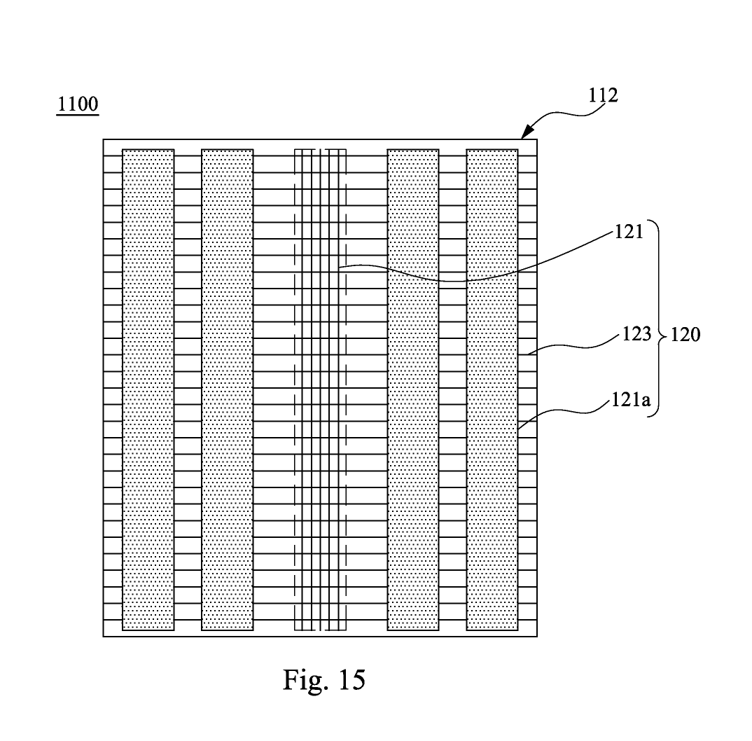

FIG. 15 is a top view of a photovoltaic cell 1100 according to the eleventh embodiment of the present invention. The difference between the eleventh embodiment and the first embodiment includes that the bus electrode 121 having the line electrodes and the band electrodes 121a taken together are five in quantity.

It should be noted that the quantity of the bus electrode 121 and the band electrodes 121a described above is only an example but not used to limit the scope of the present invention, indicating that the quantity of the bus electrode 121 and the band electrodes 121a can be adjusted with respect to different needs in practice for a person having ordinary skill in the art.

To avoid redundancy, other related structural and material details in the eleventh embodiment are referenced to what is described in the first embodiment.

### WORKING EXAMPLES

Several working examples are disclosed below to explain that the photovoltaic cells of the embodiments described above could in fact provide acceptable efficiencies. To avoid redundancy, it should be noted that the parameters described above are not to be mentioned again; only those requiring further clarifications are explained hereinafter.

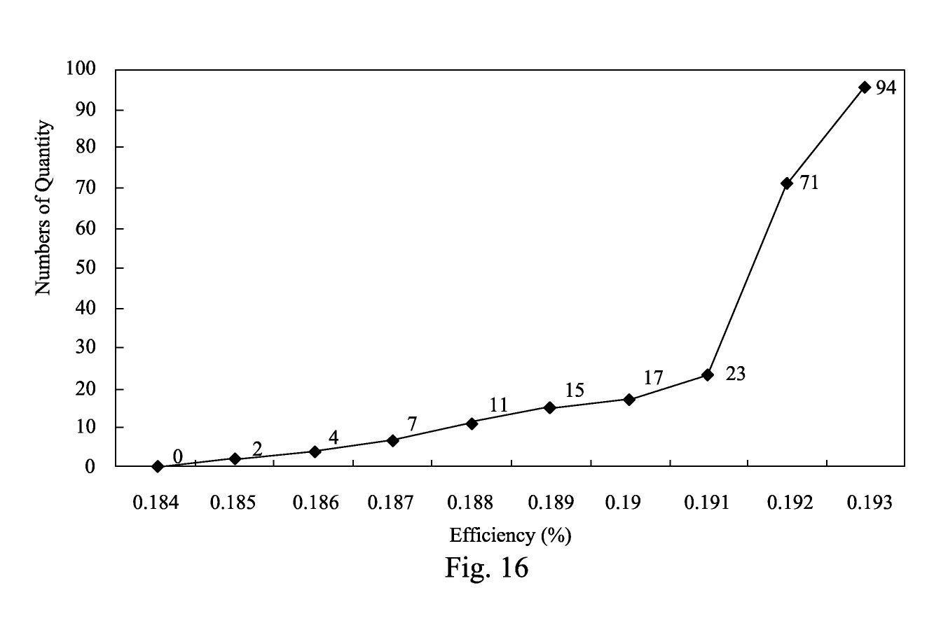

In the working examples below, a hundred pieces of photovoltaic cells 100, disclosed in the first embodiment, were provided to be measured electrical characteristics and efficiencies. Size details of the photovoltaic cells are shown in Table. 1, the experimental results are shown in Table. 2, and FIG. 16 is a graph showing cumulative numbers of photovoltaic cells versus their efficiency according to the working examples of the present invention.

TABLE 1
Size Details of the Photovoltaic Cells

| | | | | Line Width of |
|---|---|---|---|---|
| | Line Width | Interval of Line | Width | Each Finger |
| | of Each Line | Electrodes | of Bus | Electrodes |
| | Electrodes | (Edge to Edge) | Electrodes | (Edge to Edge) |
| Examples | 0.06 mm | 0.04 mm | 1.5 mm | 1.8 mm |

TABLE 2
Experimental Results

| | Open | Short | | Resistance | Resistance | |
|---|---|---|---|---|---|---|
| | Circuit | Circuit | | in | in | |
| | Voltage | Current | Filling | Series | Parallel | Efficiency |
| | (mV) | (A) | Factors | (mΩ) | (Ω) | (%) |
| Average | 0.64 | 8.99 | 79.72 | 2.15 | 321.98 | 19.19 |
| Highest | 0.64 | 9.02 | 79.92 | 1.88 | 389.65 | 19.39 |

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A photovoltaic module, comprising:
at least two photovoltaic cells, each of the photovoltaic cells comprising:
a photovoltaic device, the photovoltaic device having a light-receiving surface and a back surface opposite the light-receiving surface;
a surface electrode disposed on the light-receiving surface of the photovoltaic device, the surface electrode comprising:
at least one bus electrode, the bus electrode comprising:
at least two line electrodes disposed on the light-receiving surface; and
a plurality of finger electrodes disposed on the light-receiving surface and extending in a direction different from a lengthwise direction of the bus electrode, wherein the finger electrodes intersect and are electrically connected with the line electrodes, each of the finger electrodes is disposed partially out of a region where the bus electrode is disposed, and any adjacent two of the line electrodes and any adjacent two of the finger electrodes define an electrodeless space in the region where the bus electrode is disposed; and
a back electrode disposed on the back surface of the photovoltaic device; and
at least one ribbon electrically connecting the photovoltaic cells, wherein the ribbon is partially disposed on the light-receiving surface of the photovoltaic device of one of the photovoltaic cells and covers the line electrodes of the bus electrode.

2. The photovoltaic module according to claim 1, wherein the electrodeless space occupies about 52% to 72% of a volume of the bus electrode.

3. The photovoltaic module according to claim 1, wherein the region where the bus electrode is disposed comprises a central region and a pair of edge regions disposed on opposite sides of the central region, and the line electrodes disposed in the central region are denser than those disposed in the edge regions.

4. The photovoltaic module according to claim 3, wherein the central region occupies at least about a half of a volume of the bus electrode.

5. The photovoltaic module according to claim 1, wherein the region where the bus electrode is disposed comprises a central region and a pair of edge regions disposed on opposite sides of the central region, and a line width of each line electrode disposed in the central region are wider than those disposed in the edge regions.

6. The photovoltaic module according to claim 5, wherein the central region occupies at least about a half of a volume of the bus electrode.

7. The photovoltaic module according to claim 1, wherein line widths of the line electrodes are substantially the same.

8. The photovoltaic module according to claim 1, wherein a line width of each line electrode is wider than a line width of each finger electrode.

9. The photovoltaic module according to claim 1, wherein a line width of each line electrode is about 40 μm to 1 mm.

10. The photovoltaic module according to claim 1, wherein the line electrodes are substantially equally spaced.

11. The photovoltaic module according to claim 1, wherein intervals of the line electrodes get smaller as the intervals of line electrodes get nearer to a center of the region where the bus electrode is disposed.

12. The photovoltaic module according to claim 1, wherein the surface electrode further comprises:
at least one band electrode disposed on the light-receiving surface of the photovoltaic device, intersecting with and electrically connected with the finger electrodes, wherein a line width of the band electrode is substantially the same as a line width of the bus electrode.

13. The photovoltaic module according to claim 1, wherein a plurality of the bus electrodes are arranged separately on the light-receiving surface of the photovoltaic device.

14. The photovoltaic module according to claim 1, wherein the bus electrode further comprises:
at least a pair of end-part electrodes for constituting a shape of frame together with opposite two of the line electrodes.

15. The photovoltaic module according to claim 1, wherein a line width of each line electrode is about 40 μm to 100 μm.

16. A photovoltaic module, comprising:
at least two photovoltaic cells, each of the photovoltaic cells comprising:
a photovoltaic device, the photovoltaic device having a light-receiving surface and a back surface opposite the light-receiving surface;
a surface electrode disposed on the light-receiving surface of the photovoltaic device, the surface electrode comprising:
at least one bus electrode, the bus electrode comprising:
at least two line electrodes disposed on the light-receiving surface and any adjacent two of the line electrodes define an electrodeless space; and
a plurality of finger electrodes disposed on the light-receiving surface, wherein the finger electrodes are electrically connected to only the outermost line electrodes; and
a back electrode disposed on the back surface of the photovoltaic device; and
at least one ribbon electrically connecting the photovoltaic cells, wherein the ribbon is partially disposed on the light-receiving surface of the photovoltaic device of one of the photovoltaic cells and covers the line electrodes of the bus electrode.

17. The photovoltaic module according to claim 16, wherein the electrodeless space occupies about 52% to 72% of a volume of the bus electrode.

18. The photovoltaic module according to claim 16, wherein line widths of the line electrodes are substantially the same.

19. The photovoltaic module according to claim 16, wherein the line electrodes are substantially equally spaced.

20. The photovoltaic module according to claim 16, wherein a line width of each line electrode is about 40 μm to 1 mm.

21. The photovoltaic module according to claim 16, wherein a line width of each line electrode is about 40 μm to 100 μm.
